(19) United States
(12) Patent Application Publication
(10) Pub. No.: US 2007/0115633 A1
(43) Pub. Date: May 24, 2007

(54) Fan Cover

(75) Inventor: Chih-Peng Chuang, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/395,623

(22) Filed: Mar. 30, 2006

(30) Foreign Application Priority Data
Nov. 21, 2005 (TW) 094220114

(51) Int. Cl. H05K 7/20

(52) U.S. Cl. 361/697; 174/16.3; 165/80.3

(57) ABSTRACT

A fan cover for being mounted onto a heat sink fan with a casing is disclosed, wherein a plurality of openings are formed in the casing of the fan. The fan cover includes fan-cover body and an elastic integration unit mounted on the fan-cover body. The integration unit includes fitting parts and latching parts, wherein the fitting parts can be engaged with the openings, and the latching parts are located on the fitting parts and can be coupled to the casing of the fan. In comparison to a conventional metal fan cover having disadvantages such as high production costs and laborious installation procedures, the above fan cover is relatively cheaper to make and easier to install.

### FIELD OF THE INVENTION

The invention relates to fan covers, and more particularly, to a fan cover designed for heat sink fans installed inside computers or server appliances.

### BACKGROUND OF THE INVENTION

As the design and manufacturing technology of integrated circuit continues to advance, its degree of integration has also been elevated along the way. One case in point is the server systems that employ a large number of integrated circuits. For the purpose of increasing data processing speed and making efficient use of available spaces, the common practice is to install multiple integrated circuits such as CPUs (Central Processing Units) and graphic chips into a small space, which in turn generates large amounts of heat while they are running. Moreover, these systems are always equipped with external cases in order to protect the server systems, thus when these heat-generating integrated circuits are actually running, problem like inefficient beat dissipation often arises and further affects the normal functions of the server systems. Installing a heat sink fan device is usually a cost-effective and efficient way to dissipate the heat generated by integrated circuits while they are running.

Please refer to FIG. 1, which shows the structure of a heat sink fan produced in accordance with the prior art. It has a fan cover 14 installed at draft direction 12 of fan blade 10 in heat sink fan 1. As shown by the figure, the fan cover 14 is fixated on the parts of casing 18 that surround fan blade 10 of heat sink fan 1 by four screws 16, so that fan blade 10 and the integrated circuits next to heat sink fan 1 will not be damaged by colliding with foreign objects.

Although the fan cover described above is effective for protecting heat sink fan, it requires four fixing components like screws to fixate the fan cover at the draft direction for one single heat sink fan. When it is applied in server systems or other such devices that need a large number of heat sink fans, the quantity of necessary protection frames and the required labor for installing the protection frames will take up a lot of hardware budget and installation time. Furthermore, when it becomes necessary to remove heat sink fans, the removal process cannot be completed without an ancillary tool like a screwdriver, which further complicates the process and makes it more inconvenient.

Referring to FIG. 2, which shows the structure of a heat sink fan produced in accordance with another prior art. It has a fan cover 5 installed at the draft direction of fan blade 20 in heat sink fan 2. As indicated in the figure, the fan cover 5 is fixated on the pin-hole 25 surrounding heat sink fan 2 by rivet 6. The rivet 6 is consisted of a first holding part 60 and a second holding part 61, and fan cover 5 and heat sink fan 2 are sandwiched between these two holding parts, so that fan cover 5 is fixated securely by rivet 6.

Though installing fan cover by rivets does not require tools, it does require more labor for working with rivets, and the job becomes even trickier during the removal of fan cover, because the holding parts are difficult to hold on to and need to be handled with particular skills. Due to the need to work with the holding parts with more labor and particular skills, the fan cover has to be made of metal materials with extra strength, thus the production cost of fan cover has always remains high.

Therefore, it is urgent to develop a fan cover with low production cost and easy, labor-saving installation steps.

### SUMMARY OF THE INVENTION

In light of the shortcomings of the prior arts, an objective of the present invention is to provide a fan cover that can be quickly installed on and removed from the heat sink fan.

Another objective of the present invention is to provide a fan cover that can be installed on and removed from the heat sink fan in a labor-saving fashion.

A further objective of the present invention is to provide a fan cover that can be produced at a lower cost.

To achieve the objectives described above, the present invention provides a fan cover for mounting onto heat sink fans with casing, and the casing has a plurality of openings located on it; the fan cover is comprised of: the fan-cover body and the elastic integration parts located on the fan-cover body. The integration part is consisted of: fitting parts that are in alignment with the openings and can be fitted through the openings, along with latching parts located on the fitting parts for snapping onto the casing.

The fan cover is made of plastic materials, and the fitting parts are formed as pins, the latching parts face the direction away from the center of the fan cover, and are formed as snaps in the style of a hook that protrude outward from the end of the fitting parts. In addition, the fan cover also includes fortified wedges that are formed at the boundaries between the fitting parts and the fan-cover body.

In comparison to the installation and removal processes of fan covers from prior arts, which are complicated and laborious, the fan cover of the present invention is easy and more labor-saving to assemble. Firstly, start by aligning the integration units to the openings in the casing of the heat sink fan, then pressing the fan cover in the direction of heat sink fan until the snaps on the end of integration units have gone through the casing of heat sink fan, at this point the snaps can snap onto the casing of heat sink fan by the elasticity of the integration units. When it is necessary to remove the fan cover, the fan cover can be easily removed by pushing down the snaps to unfasten them from the casing of heat sink fan.

Moreover, since the fan cover is made of plastic, it is lighter in weight and more cost-effective to make than the metal fan covers.

In summary, the fan cover of the present invention can be produced at low costs and assembled in an easy and labor-saving fashion. Furthermore, its function of protecting the heat sink fan is as strong as the fan covers of prior arts. The collective merits make the fan cover of the present invention highly valuable from the perspective of the industry.

### BRIEF DESCRIPTION OF THE DRAWINGS

The present invention can be more fully understood by reading the detailed description of the preferred embodiments listed below, with reference made to the accompanying drawings, wherein:

FIG. 1 (PRIOR ART) is a schematic view showing the method of fixating a fan cover onto a heat sink fan by screws;

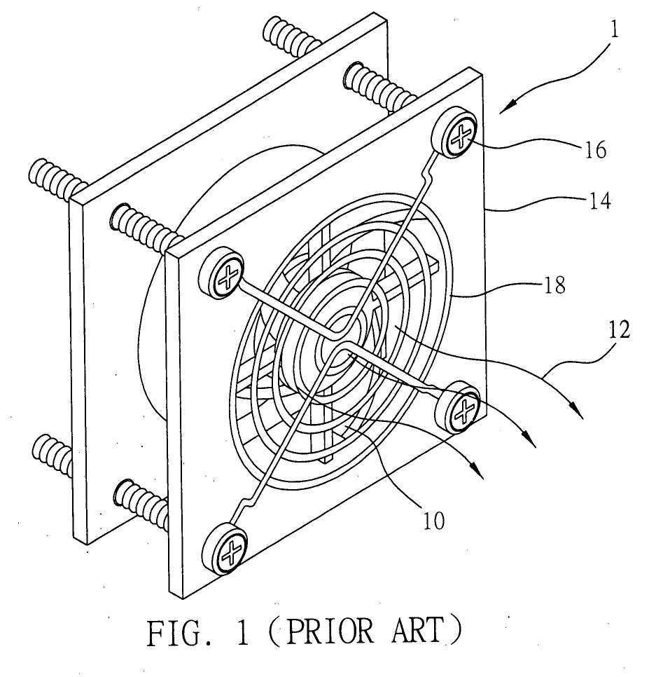

FIG. 2 (PRIOR ART) is a schematic view showing the method of fixating a fan cover onto a heat sink fan by rivets;

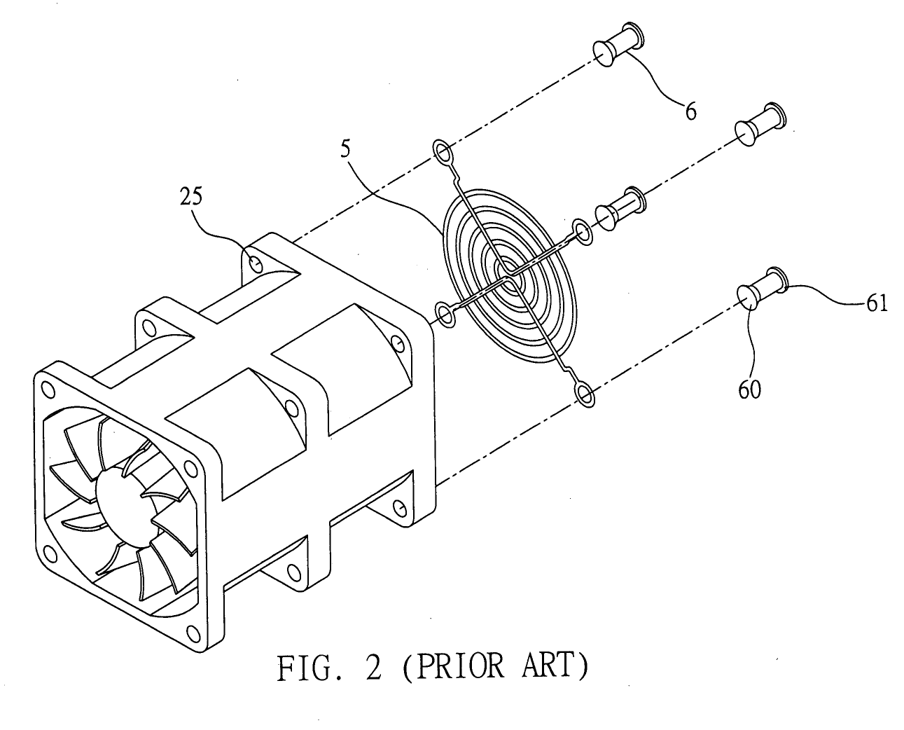

FIG. 3 is a schematic view illustrating the heat sink fan that corresponds to the fan cover of the present invention;

FIG. 4 is a schematic view showing the fan cover according to a preferred embodiment of the present invention; and

FIG. 5A to 5B are schematic views illustrating the assembling process of fan cover and heat sink fan according to a preferred embodiment of the present invention.

Please also note that the aforementioned drawings are merely the simplified views for elucidating the basic idea of the present invention in a schematic way. Hence the drawings show only the relevant components of the present invention, they are not drawn in accordance with the actual number, shape, and size of the components. The actual status, number, and proportion of each component can be adjusted randomly, and the allocation of the components could be more complicated than what is shown in the drawings.

### DETAILED DESCRIPTION OF THE PREFERRED EMBODIMENTS

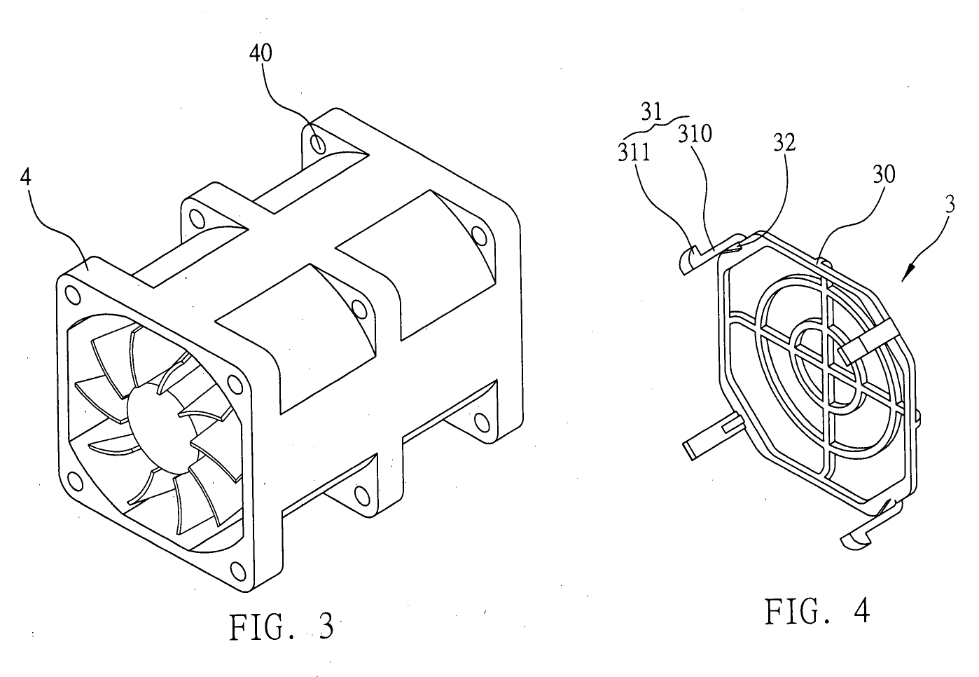

FIG. 3 shows a heat sink fan 4 with casing that corresponds to the fan cover of the present invention; it has one opening 40 in each of the four corners.

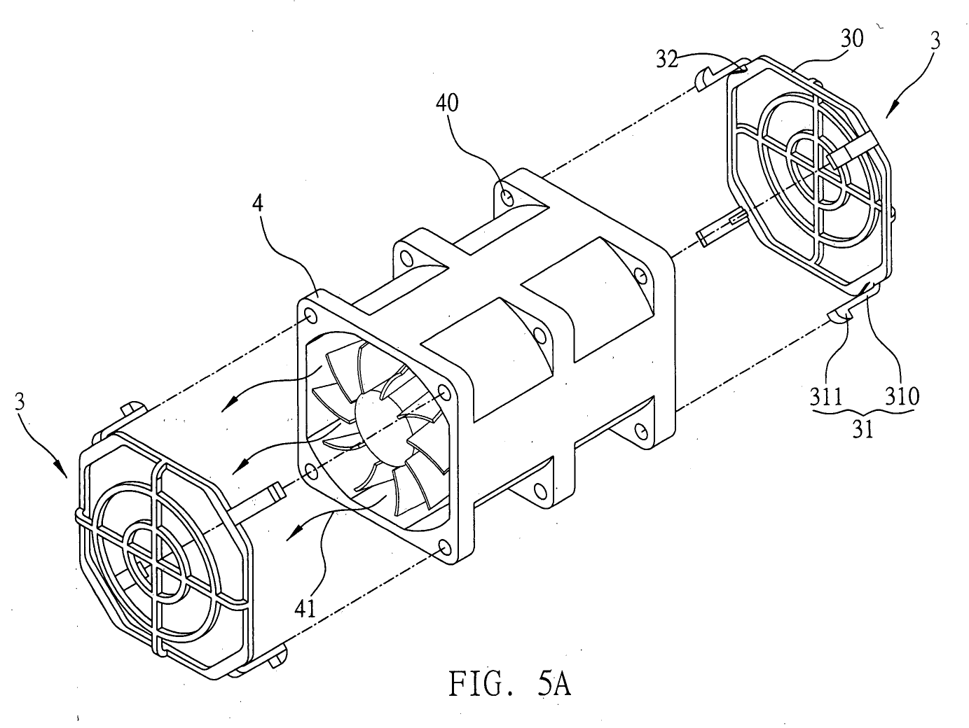

A preferred embodiment of the fan cover in accordance with the present invention is shown in FIG. 4. A fan cover 3 is comprised of a fan-cover body 30 made of plastic materials; and four elastic integration units 31 are formed on the fan-cover body 30; the integration units 31 are in alignment with the position of openings 40 of heat sink fan 4.

A plurality of openings are also formed in fan-cover body 30 to facilitate the flow of air.

An integration unit 31 is consisted of: a fitting part 310 and a latching part 311 located on the end of fitting part 310. The fitting part 310 can be a pin perpendicular to fan-cover body 30, which is fitted into opening 40. The latching part 311 can be a snap fashioned in the style of a hook, which protrudes outward from the end of fitting part 310. It should also be noted that the size of fan cover 3 can be adjusted to make it compatible with the size of heat sink fan; it is not limited to the size mentioned here.

The fan cover 3 also includes four fortified wedges formed on the bottom of integration unit 31 and the surface of fan-cover body 30, so that the strength of the connection between integration unit 31 and fan-cover body 30 is fortified.

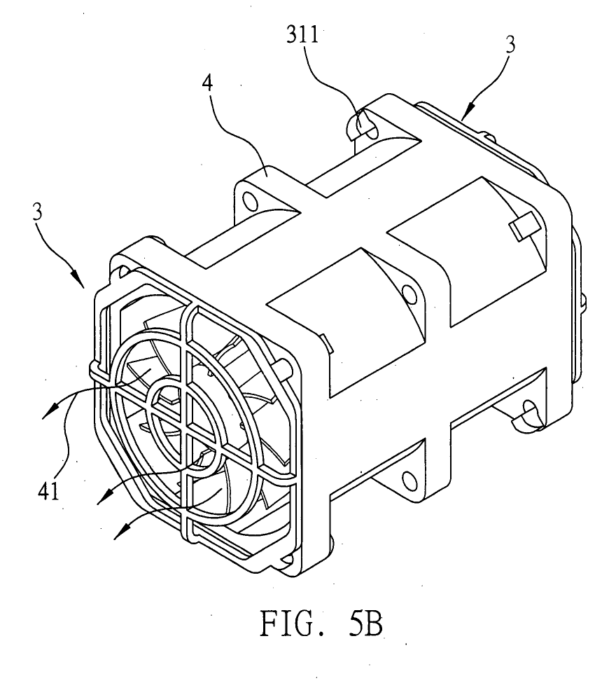

FIGS. 5A and 5B illustrate the procedures for mounting fan cover 3 onto heat sink fan 4 and vice versa.

To mount fan cover 3 onto heat sink fan 4 so that it ends up at the side of draft direction 41, one should start by aligning each of the integration unit 31 to its corresponding openings 40, and then pushing the integration units 31 completely into openings 40. This is followed by pressing fan cover 3 towards the direction of heat sink fan 4 until the fitting parts 311 have gone through openings 40 and snap onto the other side of openings 40; thereby completing the mounting process.

On the other hand, dismounting can be easily achieved by pushing down latching parts 311 until they are unfastened, then fan cover 3 can be easily removed from heat sink fan 4. The fan cover 3 of the present invention can snap onto the heat sink fan 4 by the elasticity of integration units 31 located on the four corners of fan cover 3. When all of the integration units 31 are fitted through openings 40 at the same time, the hook-shaped latching parts 311 protruding outward from the end of the fitting parts 310 are compressed; once the latching parts 311 have been completely fitted through openings 40, the force of compression is released, thereby allowing the latching parts 311 to snap onto the parts of the casing in proximity to openings 40 in heat sink fan 4.

With comparison to fan cover of prior arts, which require a separate component to fix the fan cover on a heat sink fan, the fan cover of the present invention and the components it required for securing itself are formed as one complete piece, which in turn facilitates the installation process.

Moreover, with respect to the fan cover of the present invention, its installation process can be easily accomplished by aligning the integration units to the openings in heat sink fan and then fitting them completely through the openings. As a result, the installation has been made a lot easier because screws and rivets are no longer needed to secure the fan cover.

Furthermore, the fan cover of the present invention simply utilizes the elasticity of materials for the purpose of securing itself, that is, it allows the fan cover to snap onto the heat sink fan by itself. In the preferred embodiment of the present invention, the integration unit of the fan cover is perpendicular to the fan-cover body, which allows the installation process to be completed by minimal compression force. Therefore, the labor needed to complete installation in this case is comparatively less than that of securing components with rivets.

In addition, because the labor required to complete installation is relatively less, the risk of damaging fan cover accidentally during installation is minimized, thus the fan cover of the present invention can be made of plastic materials. As a result, it not only has advantages like low production costs and decent elasticity, it is also as strong as the metal fan cover in terms of protecting heat sink fan.

In summary, the fan cover of the present invention possesses special properties like easy, labor-saving installation and low production costs; additionally, it has also passed the industrial drop test, which made it highly valuable from the perspective of the industry.

It is to be understood that the embodiments described herein are merely illustrative of the principles of the present invention, and the scope of the present invention is not limited to the disclosed embodiments. In contrast, it is intended to cover various modifications and similar arrangements, therefore, the scope of the claims should be interpreted in the broadest sense so as to encompass all such modifications and similar arrangements.

What is claimed is:

1. A fan cover for being mounted onto a heat sink fan having a casing, with a plurality of openings being formed in the casing, the fan cover comprising:
a fan cover body; and
an elastic integration unit mounted to the fan-cover body, the integration unit comprising fitting parts for being engaged with the openings, and latching parts mounted to the fitting parts and for being coupled to the casing.

2. The fan cover of claim 1, wherein the fan-cover body is made of a plastic material.

3. The fan cover of claim 1, wherein the integration unit is formed as one piece with the fan-cover body.

4. The fan cover of claim 1, wherein the fitting parts are formed as pins for fitting the openings.

5. The fan cover of claim 1, wherein the latching parts are formed as hooks and protrude outward from the fitting parts, so as to allow the latching parts to hook parts of the casing in proximity to the openings.

6. The fan cover of claim 1, further comprising fortified wedges for connecting the integration unit and the fan-cover body, so as to fortify strength of connection between the integration unit and the fan-cover body.

7. The fan cover of claim 1, wherein a plurality of openings are formed in the fan-cover body to facilitate flow of air.
